(19) United States
(12) Patent Application Publication
(10) Pub. No.: US 2013/0025681 A1
(43) Pub. Date: Jan. 31, 2013

(54) ELECTROLYTE FOR DYE-SENSITIZED SOLAR CELL AND DYE-SENSITIZED SOLAR CELL USING THE SAME

(71) Applicants: Moon-Sung Kang, Yongin-si (KR); Ji-Won Lee, Yongin-si (KR); Si-Young Cha, Yongin-si (KR); Yong-Soo Kang, Seongdong-gu (KR); Dong-Hoon Song, Seongdong-gu (KR)

(72) Inventors: Moon-Sung Kang, Yongin-si (KR); Ji-Won Lee, Yongin-si (KR); Si-Young Cha, Yongin-si (KR); Yong-Soo Kang, Seongdong-gu (KR); Dong-Hoon Song, Seongdong-gu (KR)

(73) Assignee: Samsung SDI Co., Ltd., Yongin-si (KR)

(21) Appl. No.: 13/410,003

(22) Filed: Mar. 1, 2012

(30) Foreign Application Priority Data
Jul. 29, 2011 (KR) 10-2011-0076140

(51) Int. Cl. H01L 51/44; C09K 3/00

(52) U.S. Cl. 136/263; 252/62.2

(57) ABSTRACT

An electrolyte for a solar cell comprising a heterogeneous redox couple comprising iodide and a pseudohalogen and a dye-sensitized solar cell including the electrolyte is provided.

### CROSS-REFERENCE TO RELATED APPLICATION

This application claims the benefit of Korean Patent Application No. 10-2011-0076140, filed on Jul. 29, 2011, in the Korean Intellectual Property Office, the disclosure of which is incorporated herein in its entirety by reference.

### BACKGROUND

1. Field

One or more embodiments relate to an electrolyte for a dye-sensitized solar cell and a dye-sensitized solar cell using the same.

2. Description of the Related Technology

A dye-sensitized solar cell consists of a photocathode on which dye molecules are adsorbed, an electrolyte containing a redox ion couple, and a counter electrode including a platinum catalyst. By irradiating the dye molecules with light, the dye molecules are excited from a ground state to an excited state and electrons thereof are transferred to a semiconductor layer. The excited electrons migrate to the counter electrode through external wiring, and then the redox couple oxidized by the catalyst coated on a surface of the counter electrode is reduced. The reduced redox couple reduces the oxidized dye molecules and thus the dye molecules again have electrons capable of entering the excited state. A conduction band of the semiconductor layer and a potential difference of the redox couple indicate an open circuit voltage (Voc).

A redox couple in an electrolyte in a dye-sensitized solar cell is a material included for electron transfer, and can consist of iodide (I)-based, bromine (Br)-based, cobalt (Co)-based, thiocyanate ([SCN])-based, or selenocyanate ([SeCN]⁻)-based homogeneous elements. Specifically, redox couples consisting of homogeneous elements, such as I⁻/I₃⁻, SCN⁻/(SCN)₂, and SeCN—/(SeCN)₂, are generally used.

Iodide-based redox couples I⁻/I₃⁻ are usually used. However, energy conversion efficiency and durability of such redox couples do not reach satisfactory levels.

### SUMMARY

One or more embodiments provide an electrolyte for a dye-sensitized solar cell including a heterogeneous redox couple containing iodide and a pseudohalogen compound.

One or more embodiments provide an electrolyte for a dye-sensitized solar cell wherein the heterogeneous redox couple is I—/(SeCN)₂.

One or more embodiments provide a solar cell including the electrolyte for a dye-sensitized solar cell.

Additional aspects will be set forth in part in the description which follows and, in part, will be apparent from the description, or may be learned by practice of the presented embodiments.

According to one or more embodiments, an electrolyte for a dye-sensitized solar cell includes a heterogeneous redox couple containing iodide and a pseudohalogen compound.

In some embodiments, the pseudohalogen compound can be a combination of one or more components each independently selected from the group consisting of (CN)₂, (SCN)₂, (SeCN)₂, azide ion (N₃), SCSN₃, etc. and one or more pseudohalide ions selected from the group consisting of CN⁻, SCN⁻, SeCN⁻, OCN⁻, etc.

In some embodiments, the heterogeneous redox couple may be I⁻/(SeCN)₂. In some embodiments, the iodide comprises one or more components each independently selected from the group consisting of imidazolium iodide, pyridinium iodide, alkali metal iodide, ammonium iodide, and pyrrolidinium iodide. In some embodiments, a pseudohalogen/iodide molar ratio is from about 0.001 to about 10. In some embodiments, a concentration of the iodide is from about 0.5 to about 1.0 M. In some embodiments, a concentration of the (SeCN)₂ is from about 0.05 to about 0.3 M. In some embodiments, the electrolyte further comprises an organic solvent. In some embodiments, the organic solvent has a boiling point of about 150° C. or more. In some embodiments, the organic solvent is one or more components each independently selected from the group consisting of γ-butyrolactone (GBL), N-methyl-2-pyrrolidone (NMP), benzonitrile (BN), dimethylsulfoxide (DMSO), dimethyl acetamide (DMAA), N,N-dimethylethanamide (DMEA), 3-methoxypropionitrile (MPN), diglyme, diethylformamide (DEF), and dimethylformamide (DMF).

According to one or more embodiments, a dye-sensitized solar cell includes a first electrode; a light absorption layer formed on either side of the first electrode; a second electrode disposed to face the first electrode where the light absorption layer is formed; and an electrolyte disposed between the first electrode and the second electrode and including a heterogeneous redox couple containing iodide and a pseudohalogen compound. In some embodiments, the pseudohalogen is one or more components each independently selected from the group consisting of (CN)₂, (SCN)₂, (SeCN)₂, azide ion (N₃), SCSN₃, CN⁻, SCN⁻, SeCN⁻, and OCN⁻. In some embodiments, the heterogeneous redox couple is I—/(SeCN)₂. In some embodiments, the iodide comprises one or more components each independently selected from the group consisting of imidazolium iodide, pyridinium iodide, alkali metal iodide, ammonium iodide, and pyrrolidinium iodide. In some embodiments, a pseudohalogen/iodide molar ratio is from about 0.001 to about 10. In some embodiments, the dye-sensitized solar cell further comprises dye molecules.

### BRIEF DESCRIPTION OF THE DRAWINGS

These and/or other aspects will become apparent and more readily appreciated from the following description of the embodiments, taken in conjunction with the accompanying drawings of which:

FIG. 1 illustrates a redox potential for each of redox couples of electrolytes for dye-sensitized solar cells;

FIG. 2 is a schematic view illustrating an operating principle of a dye-sensitized solar cell;

FIG. 3 illustrates a schematic structure of a dye-sensitized solar cell according to an aspect of the present embodiments;

FIG. 4 is a graph showing characteristics of voltage and current according to Example 1 and Comparative Example 1; and

FIG. 5 is a graph showing efficiency characteristics according to Example 1 and Comparative Example 1 over time.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description.

Hereinafter, according to one or more exemplary embodiments, an electrolyte for a dye-sensitized solar cell and a solar cell employing the same will be described in more detail with reference to accompanying drawings.

An electrolyte for a dye-sensitized solar cell according to an embodiment includes a heterogeneous redox couple including one or more selected from the group consisting of iodide and a pseudohalogen.

As used herein, the term “pseudohalogen” refers to a compound having a group exhibiting properties similar to those of halogen atoms or properties similar to those of a halogen in which two such groups are bound, and corresponds to a pseudohalogen compound or a pseudohalogen ion. For example, the pseudohalogen compound may be (CN)₂, (SCN)₂, (SeCN)₂, azide ion (N₃), or SCSN₃, and the pseudohalogen ion may be CN⁻, SCN⁻, SeCN⁻, or OCN⁻.

The term “iodide” refers to iodine, an iodide ion, or an iodide containing compound.

In some embodiments, the heterogeneous redox couple employs existing I⁻ as a reducing agent and employs a pseudohalogen in order to form an oxidizing agent, and thus may provide a higher ion diffusion coefficient and higher voltage characteristics than existing iodide-based homogeneous redox couples. In addition, the amount of the pseudohalogen in the electrolyte for a dye-sensitized solar cell is smaller than the amount of a pseudohalogen in a homogeneous pseudohalogen electrolyte using only the pseudohalogen to form a redox couple, and thus the heterogeneous redox couple is excellent environmentally and in terms of stability with respect to the addition of pseudohalogens.

In some embodiments, the pseudohalogen/iodide molar ratio may be about 0.001 to about 10.

When the pseudohalogen/iodide molar ratio is in the above range, stability of the electrolyte for a dye-sensitized solar cell can be excellent.

In some embodiments, the concentration of iodide in the heterogeneous redox couple may be about 0.5 to about 1.0 M, and a concentration of (SeCN)₂ in the heterogeneous redox couple may be about 0.05 to about 0.3 M.

For example, the heterogeneous redox couple in the electrolyte for a dye-sensitized solar cell may be I—/(SeCN)₂, but is not limited thereto.

In addition, the heterogeneous redox couple I—/(SeCN)₂ can be excellent environmentally and in terms of stability because the amount of Se in the heterogeneous redox couple is about 1/10th the amount of Se in existing homogeneous redox couples SeCN—/(SeCN)₂.

In some embodiments, the heterogeneous redox couple I—/(SeCN)₂ may employ existing I⁻ as a reducing agent and employ (SeCN)₂ in order to form an oxidizing agent. Through this, performance of the electrolytes using the heterogeneous redox couple can be equivalent to or better than that of existing iodide-based electrolyte and stability of the electrolyte may be improved.

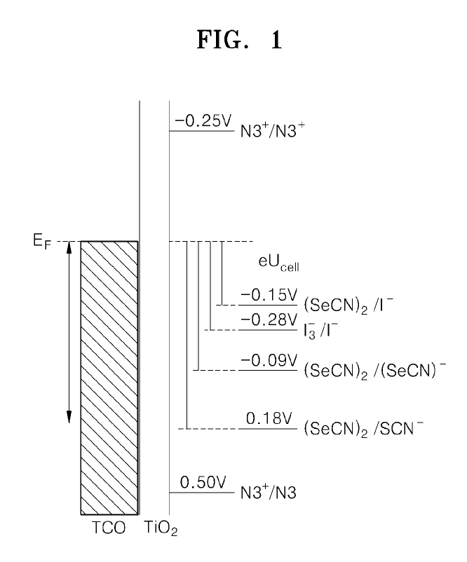

FIG. 1 shows a redox potential for each of redox couples of electrolytes for dye-sensitized solar cells. As shown in FIG. 1, the heterogeneous redox couple of the present invention including one or more selected from the group consisting of iodide and a pseudohalogen compound may have a higher voltage than a homogeneous redox couple I⁻/I₃⁻ because the redox potential of the heterogeneous redox couple has a positive shift. The heterogeneous redox couple may have a more negative energy level than the HOMO (Higher Order Molecular Orbital) position of a typical photosensitive dye, and thus may deliver electrons to dye molecules in a ground state more easily.

An electron delivery reaction mechanism of the heterogeneous redox couple I⁻/(SeCN)₂ according to an aspect of the present embodiments is represented by the following Formula 1.

I(SeCN)₂⁻+2e⁻→I⁻+2(SeCN)⁻ Formula 1

In some embodiments, an iodide ion (I—) may be provided from an iodide of a nitrogen-containing heterocyclic compound, such as an imidazolium salt, a pyridinium salt, a quaternary ammonium salt, a pyrrolidinium salt, a pyralidinium salt, a pyrazolidium salt, an isothiazolidinium salt, an isooxazolidinium salt, etc. For example, the iodide ion may be provided from imidazolium iodide, pyridinium iodide, alkalimetal iodide, ammonium iodide, pyrrolidinium iodide, etc.

In some embodiments, the electrolyte for a dye-sensitized solar cell may further include an organic solvent. According to an aspect of the present embodiments, the organic solvent may have a boiling point of about 120° C. or more, and may include, for example, propanediol-1,2-carbonate (PDC), ethylene carbonate (EC), diethylene glycol (DEG), propylene carbonate (PC), hexamethylphosphoric triamide (HMPA), ethyl acetate, nitrobenzene, formamide, γ-butyrolactone (GBL), benzyl alcohol, N-methyl-2-pyrrolidone (NMP), acetophenone, ethylene glycol, trifluorophosphate, benzonitrile, dimethylsulfoxide (DMSO), dimethyl sulfate, aninline, N-methylformamide (NMF), phenol, 1,2-dichlorobenzene, tri-n-butyl phosphate, o-dichlorobenzene, selenium oxychloride, ethylene sulfate, benzenethiol, dimethyl acetamide (DMA), N,N-dimethylethanamide, 3-methoxypropionitrile, diglyme, cyclohexaneol, bromobenzene, cyclohexanone, anisole, diethylformamide, dimethylformamide (DMF), 1-hex anethiol, hydrogen peroxide, bromoform, ethylchloroacetate, 1-dodecanethiol, di-n-butyl ether, dibutyl ether, acetic anhydride, m-xylene, p-xylene, chlorobenzene, morpholine, diisopropyl ethylamine, diethyl carbonate (DEC), 1-pentanediol, or n-butyl acetate 1-hexadecanethiol.

According to another aspect of the present embodiments, the organic solvent may have a boiling point of about 150° C. or more, and includes, for example, γ-butyrolactone (GBL), N-methyl-2-pyrrolidone (NMP), benzonitrile (BN), dimethylsulfoxide (DMSO), dimethyl acetamide (DMAA), N,N-dimethylethanamide (DMEA), 3-methoxypropionitrile, diglyme, diethylformamide (DEF), or dimethylformamide (DMF).

In some embodiments, iodide may be included in an amount of about 0.3 to about 1.5 M, for example, about 0.5 to about 1.0 M, in the electrolyte for a dye-sensitized solar cell. In the above concentration range, delivery of electrons to a dye in a ground state through a reversible redox reaction can occur more easily.

In some embodiments, (SeCN)₂ may be included in an amount of about 0.01 to about 0.5 mol/l, for example, about 0.05 to about 0.3 mol/f, in the electrolyte for a dye-sensitized solar cell. In the above concentration range, selenium is present in a relatively small amount, and thus the electrolyte for a dye-sensitized solar cell is excellent environmentally and in terms of stability, compared to similar pseudohalogen-based homogeneous redox couple electrolytes.

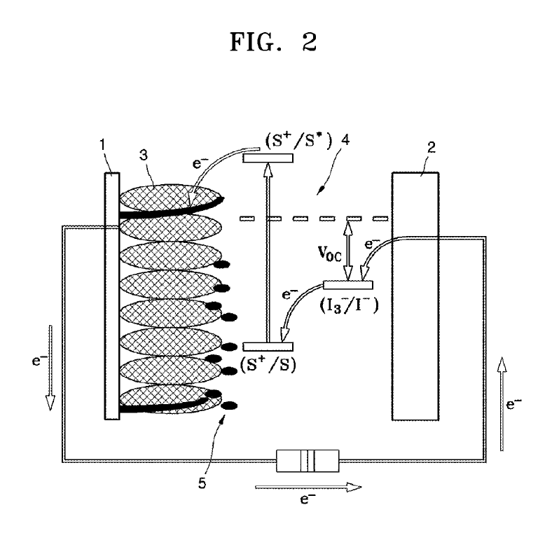

FIG. 2 shows an operating principle of a general dye-sensitized solar cell. Electron-hole pairs can be created as the dye molecules 5 are excited from a ground state to an excited state and then electrons thereof can be transferred away from the dye molecules 5 if solar light rays are absorbed by dye molecules 5. The excited electrons can be injected into a conduction band at an interface of particles of a porous membrane 3, and then the injected electrons can be transferred to a first electrode 1 through an interface with the first electrode 1 and then transferred to a second electrode 2 through an external circuit. The dye molecules 5 oxidized as a result of the electron transfer can be reduced by iodide ions (F) of redox couples in an electrolyte solution 4, and the oxidized iodide ions, that is, trivalent iodide ions (I₃⁻), are involved in a reduction reaction with electrons that have arrived at an interface of the second electrode 2 in order to achieve charge neutrality to operate the cell. In some embodiments, the dye-sensitized solar cell can use an electrochemical principle of operating the cell through reactions at an interface, unlike existing p-n junction type silicon-based solar cells.

According to another embodiment, there can be provided a dye-sensitized solar cell including a first electrode; a light absorption layer formed on a side of the first electrode; a second electrode disposed to face the first electrode on which the light absorption layer is formed; and an electrolyte disposed between the first electrode and the second electrode.

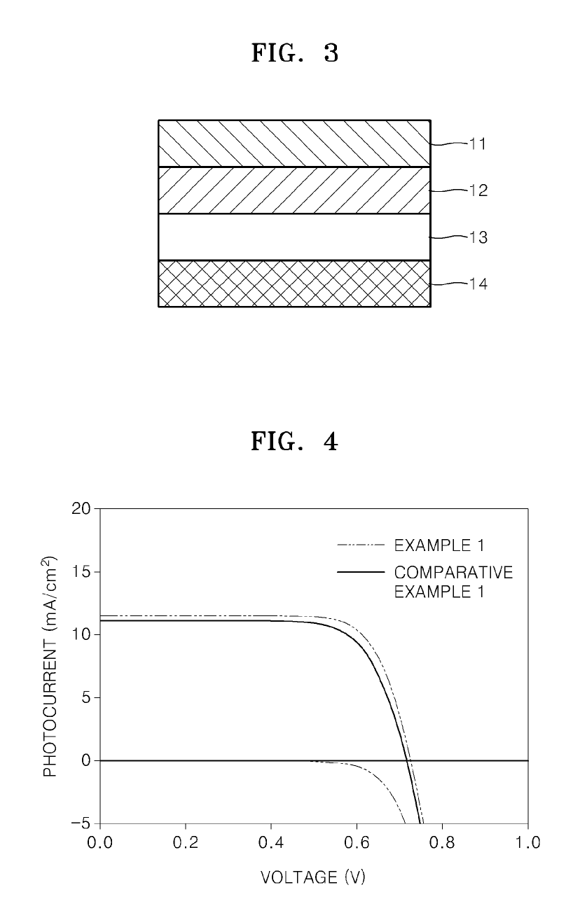

FIG. 3 schematically illustrates an example of the dye-sensitized solar cell. The solar cell includes a first electrode 11, a light absorption layer 12, an electrolyte 13, and a second electrode 14, and the light absorption layer 12 may include semiconductor particles and dye molecules. The first electrode 11 and the light absorption layer 12 can be collectively called a semiconductor electrode.

In some embodiments, the electrode 13 can be as described above.

In some embodiments, the first electrode 11 may include a transparent substrate and a conductive layer formed on the transparent substrate. In some embodiments, the transparent substrate may be formed of any suitable transparent material that transmits external light without particular limitation. In some embodiments, the transparent substrate may be formed of glass or plastic. Specific examples of the plastic may include polyethylene terephthalate (PET), polyethylene naphthalate (PEN), polycarbonate (PC), polypropylene (PP), polyimide (PI), triacetyl cellulose (TAC), polyethersulfone, and copolymers thereof.

In some embodiments, the transparent substrate may be doped with a doping material selected from the group consisting of titanium (Ti), indium (In), gallium (Ga), and aluminum (Al).

In some embodiments, the conductive layer can be disposed on the transparent substrate.

In some embodiments, the conductive layer may include a conductive metal oxide selected from the group consisting of indium tin oxide (ITO), fluorine tin oxide (FTO), ZnO—(Ga₂O₃ or Al₂O₃), a tin-based oxide, antimony tin oxide (ATO), zinc oxide, and combinations thereof. For example, SnO₂ may be used for its suitable conductivity, transparency, and heat resistance, indium tin oxide (ITO) may be used relatively inexpensively and alone, and a complex layer of indium tin oxide (ITO) and other heterogeneous metal oxide layers may be used in order to reduce resistance after heat treatment.

In some embodiments, the conductive layer may be formed of a single-layer film or a multi-layer film of the conductive metal oxide.

In some embodiments, a porous membrane including the semiconductor particulates and the light absorption layer 12 including the photosensitive dye molecules adsorbed on a surface of the porous membrane are formed on the first electrode 11.

In some embodiments, the porous membrane can be uniformly nanoporous, and the semiconductor particulates thereof can have a very minute and uniform average particle diameter.

In some embodiments, the semiconductor particles may be a compound semiconductor or a compound having a Perovskite structure as well as a single element semiconductor represented by silicon. In some embodiments, the semiconductor may be an n-type semiconductor that provides an anode current under optical excitation by employing electrons in a conduction band as carriers. In some embodiments, the compound semiconductor may be, for example, an oxide of a metal selected from the group consisting of titanium (Ti), zirconium (Zr), strontium (Sr), zinc (Zn), indium (In), ytterbium (Yr), lanthanum (La), vanadium (V), molybdenum (Mo), tungsten (W), tin (Sn), niobium (Nb), magnesium (Mg), aluminum (Al), yttrium (Y), scandium (Sc), samarium (Sm), gallium (Ga), indium (In), and TiSr. The compound semiconductor may be titanium dioxide (TiO₂), tin oxide (SnO₂), zinc oxide (ZnO), tungsten oxide (WO₃), niobium oxide (Nb₂O₅), and strontium titanate (TiSrO₃), or a mixture thereof. In some embodiments, the compound semiconductor may be anatase type TiO₂. The semiconductor particles are not limited to the above-mentioned materials, and the above-mentioned materials may be used alone or in a combination thereof. In some embodiments, the semiconductor particulates may have a relatively large surface area to allow the dye molecules adsorbed onto a surface of the semiconductor particulates to absorb a relatively great amount of light. The semiconductor particulates may have a particle diameter of about 20 nm or less.

In some embodiments, the porous membrane may be manufactured by a typical porous membrane manufacturing method. For example, the porous membrane may be manufactured by a mechanical necking treatment that does not need heat treatment and may control a membrane density of the porous membrane by appropriately controlling treatment conditions, but is not limited thereto.

In some embodiments, the dye molecules adsorbed on the surface of the porous membrane can absorb external light to produce excited electrons.

Any dye may be used without limitation as long as it is typically used in the field of solar cells, and here a ruthenium complex will be described. However, the dye is not particularly limited as long as it has a charge separation function and a photosensitizing function. Besides the ruthenium complex, the dye may be, for example, a xanthene dye, such as rhodamine B, rose bengal, eosin, erythrosine, etc., a cyanine dye, such as quinocyanine, cryptocyanine, etc., a basic dye, such as phenosafranine, capri blue, thiosine, methylene blue, etc., a porphyrin-based compound, such as chlorophyll, zinc porphyrin, magnesium porphyrin, etc., any of various azo dyes; a complex compound, such as a phthalocyanine compound, ruthenium trisbipyridyl, etc., an anthraquinone-based dye, and a polycyclic quinine-based dye, and these may be used alone or in a combination thereof. In some embodiments, the ruthenium complex may include, for example, RuL₂(SCN)₂, RuL₂(H₂O)₂, RuL₃, or RuL₂ (where L is, for example, 2,2′-bipyridyl-4,4′-dicarboxylate or other bidentate molecules).

In some embodiments, the light absorption layer 12 may have a thickness of about 15 μm or less, for example, about 1 to about 15 μm.

In some embodiments, the counter electrode 14 can be disposed to face the first electrode 11 on which the light absorption layer 12 can be formed.

Any material may be used, without limitation, as the second electrode 14 as long as it is a conductive material. In some embodiments an insulating material may be used as the second electrode 14 if a conductive layer is disposed on a side facing the semiconductor electrode. However, the conductive layer should be an electrochemically stable material that may be used as an electrode, and specific examples of the material include, but are not limited to, platinum (Pt), gold (Au), and carbon (C). In some embodiments, the side of the electrode facing the semiconductor layer is to have a fine structure and an increased surface area to improve a catalyst effect of a redox reaction. For example, when using platinum, the platinum should be in a platinum black state, and when using carbon, the carbon should be in a porous state. In some embodiments, the platinum black state may be achieved by performing an anodizing method, a platinum chloride acid treatment, or the like on platinum. In some embodiments, the porous state may be achieved by performing a method of sintering carbon microparticles, a method of sintering an organic polymer, or the like on carbon.

Methods of manufacturing a solar cell with the above-described structure are well known in the art and are understood by those skilled in the art.

The present embodiments are described in more detail with reference to examples and comparative examples below. The following examples are for illustrative purposes only and are not intended to limit the scope of the embodiments.

### Preparation Example 1

### Preparation of Electrolyte

For the synthesis of an (SeCN)₂ powder, 6 g of KSeCN and 7.1 g of AgNO₃ were first dissolved at a molar ratio of 1:1 in 20 g of ultrapure water. A precipitate was produced according to the following reaction and collected by filtration to obtain AgSeCN.

KSeCN+AgNO₃→AgSeCN

Subsequently, 4.3 g of AgSeCN was dissolved in 20 g of methylene chloride (DCM), 2.6 g of iodine (I₂) was added to the solution, and (SeCN)₂ was produced according to the following reaction.

2AgSeCN+I₂→(SeCN)₂+2AgI

AgI was precipitated according to the reaction, (SeCN)₂ was obtained in a solution state, and the solvent was evaporated to obtain an (SeCN)₂ powder.

All reagents used in the process were purchased from Aldrich (St. Louis, Mo.) and used without further purification.

As a solvent for preparing an electrolyte, 3-methoxypropionitrile (MPN) was purchased from Aldrich and used without further purification. 1.0 M of 1-butyl-3-methyl imidazolium iodide (BMImI) and 0.1 M of (SeCN)₂ were dissolved in 10 g of 3-methoxypropionitrile to prepare an electrolyte.

### Comparative Preparation Example 1

### Preparation of Electrolyte

In order to prepare an iodide electrolyte, 3-methoxypropionitrile (MPN) was used as a solvent and 2.7 g and 0.26 g of 1-butyl-3-methyl imidazolium iodide (BM1 ml) were dissolved in 10 g of 3-methoxypropionitrile, respectively, to prepare 1.0 M 1-butyl-3-methyl imidazolium iodide (BMImI) and 0.1 M I₂ electrolytes. All reagents used in the process were purchased from Aldrich and used without further purification.

### Example 1

### Manufacture of Dye-Sensitized Solar Cell

A TiO₂ paste (PST-18NR, JGC C&C, Japan) was applied on a surface of a fluorine-containing tin oxide (FTO) substrate (thickness: about 2.3 mm) at a thickness of about 12 μm by screen printing and sintered at a heating rate of about 10° C./min at about 500° C. for 30 min, and subsequently a scattering particle paste (400 c, JGC C&C, Japan) was printed/sintered in the same manner and a photocathode with a thickness of about 4 μm was manufactured after the sintering.

The photocathode thus manufactured was immersed in a dye solution (0.2 mM N719/EtOH) and left therein for 24 hrs. A counter electrode was prepared by performing Pt sputtering on the FTO substrate for 20 min.

A hot melt film (Suryln, DuPont Wilmington, Del., 60 μm) was inserted between the photocathode and the counter electrode where holes are formed and then subjected to heat sealing (130° C./15 sec) by using a hot press. The electrolyte prepared in Preparation Example 1 was injected into holes formed in the counter electrode.

### Comparative Example 1

### Manufacture of Dye-Sensitized Solar Cell

A dye-sensitized solar cell was manufactured in the same manner as in Example 1, except that the electrolyte manufactured in Comparative Preparation Example 1 was used instead of the electrolyte prepared in Preparation Example 1.

### Evaluation Example 1

A current-voltage curve of the manufactured cell was evaluated under standard measurement conditions (AM1.5G, 100 mW cm⁻²).

In addition, conditions in which open circuit voltages, photocurrent densities, and fill factors of the dye-sensitized solar cells manufactured according to Example 1 and Comparative Example 1 were measured were as follows.

(1) Open Circuit Voltage (Voc) and Photocurrent Density

The open circuit voltages and the photocurrent densities were measured using a Keithley SMU2400 SourceMeter (Cleveland, Ohio).

(2) Energy Conversion Efficiency (R) and Fill Factor (FF)

Energy conversion efficiencies were measured by using a solar simulator (consisting of an Xe lamp [300 W, Oriel Instruments Irvine, Calif.], an AM1.5 filter, and a Keithley SMU2400) with 1.5 AM 100 mW/cm², and the fill factors were calculated by using the conversion efficiencies previously obtained and the following Calculation Formula.

$$Fill factor ( \% ) = \frac{{( J \times V )}_{max}}{{J}_{sc} \times {V}_{oc}} \times 100 \qquad Calculation Formula$$

where, J is a Y-axis value of a conversion efficiency curve, V is a X-axis value of the conversion efficiency curve, and Jsc and Voc are intercepts of each axis.

The electrolytes according to Preparation Example 1 and Comparative Preparation Example 1 were used to manufacture the dye-sensitized solar cells in Example 1 and Comparative Example 1 and measure initial efficiencies, and results are shown in the following Table 1.

TABLE 1

Initial efficiency

| | Jsc | Voc | FF | |
|---|---|---|---|---|
| Electrolyte | (mA cm⁻²) | (V) | (%) | R (%) |
| Comparative | 11.405 | 0.755 | 74.7 | 6.44 |
| Example 1 | | | | |
| (BMImI/I₂) | | | | |
| Example 1 | 11.380 | 0.767 | 75.1 | 6.56 |
| (BMImI/Se(CN)₂) | | | | |

In addition, characteristics of voltage and current of the dye-sensitized solar cells manufactured in Example 1 and Comparative Example 1 are shown in FIG. 4.

As shown in FIG. 4, it was determined that voltage and current were increased when the I—/(SeCN)₂ heterogeneous redox couple was used. The increase in voltage and the increase in current were due to a positive shift and due to enhanced ion diffusion degree, respectively.

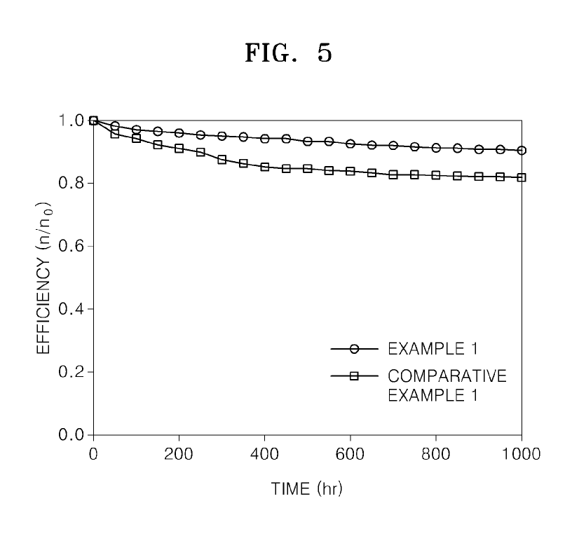

In addition, efficiency characteristics over time as a result of a high-temperature (60° C.) service-time evaluation measured under a standard light source condition of about 100 mW/cm² on the dye-sensitized solar cells of Example 1 and Comparative Example 1, which were manufactured by using the electrolytes of Preparation Example 1 and Comparative Preparation Example 1, is shown in FIG. 5.

As shown in FIG. 5, provides confirmation that the electrolyte of Preparation Example 1 was better in efficiency stability than the electrolyte of Comparative Preparation Example 1.

Efficiency in FIG. 5 indicates a ratio of efficiency (n) over time relative to initial efficiency (η₀) at a time 0, and namely, means η/η₀.

A solar cell including an electrolyte for a solar cell according to an aspect of the present embodiments allows voltage and current to increase and may have excellent electro-optical conversion efficiency and excellent efficiency stability.

It should be understood that the exemplary embodiments described therein should be considered in a descriptive sense only and not for purposes of limitation. Descriptions of features or aspects within each embodiment should typically be considered as available for other similar features or aspects in other embodiments. It will be understood by those of ordinary skill in the art that various changes in form and details may be made therein without departing from the spirit and scope of the present embodiments as defined by the following claims.

What is claimed is:

1. An electrolyte for a solar cell, comprising:
a heterogeneous redox couple comprising iodide and a pseudohalogen.

2. The electrolyte of claim 1, wherein the pseudohalogen is one or more components each independently selected from the group consisting of (CN)₂, (SCN)₂, (SeCN)₂, azide ion (N₃), SCSN₃, CN⁻, SCN⁻, SeCN⁻, and OCN⁻.

3. The electrolyte of claim 1, wherein the heterogeneous redox couple is I—/(SeCN)₂.

4. The electrolyte of claim 1, wherein the iodide comprises one or more components each independently selected from the group consisting of imidazolium iodide, pyridinium iodide, alkali metal iodide, ammonium iodide, and pyrrolidinium iodide.

5. The electrolyte of claim 1, wherein a pseudohalogen/iodide molar ratio is from about 0.001 to about 10.

6. The electrolyte of claim 3, wherein a concentration of the iodide is from about 0.5 to about 1.0 M.

7. The electrolyte of claim 3, wherein a concentration of the (SeCN)₂ is from about 0.05 to about 0.3 M.

8. The electrolyte of claim 1, further comprising an organic solvent.

9. The electrolyte of claim 8, wherein the organic solvent has a boiling point of about 120° C. or more or about 150° C. or more.

10. The electrolyte of claim 8, wherein the organic solvent is one or more components each independently selected from the group consisting of γ-butyrolactone (GBL), N-methyl-2-pyrrolidone (NMP), benzonitrile (BN), dimethylsulfoxide (DMSO), dimethyl acetamide (DMAA), N,N-dimethylethanamide (DMEA), 3-methoxypropionitrile (MPN), diglyme, diethylformamide (DEF), and dimethylformamide (DMF).

11. A dye-sensitized solar cell, comprising:
a first electrode;
a light absorption layer formed on a side of the first electrode;
a second electrode disposed to face the first electrode on which the light absorption layer is formed; and
an electrolyte disposed between the first electrode and the second electrode and including a heterogeneous redox couple comprising iodide and a pseudohalogen.

12. The dye-sensitized solar cell of claim 11, wherein the pseudohalogen is one or more components each independently selected from the group consisting of (CN)₂, (SCN)₂, (SeCN)₂, azide ion (N₃), SCSN₃, CN⁻, SCN⁻, SeCN⁻, and OCN⁻.

13. The dye-sensitized solar cell of claim 11, wherein the heterogeneous redox couple is I—/(SeCN)₂.

14. The dye-sensitized solar cell of claim 11, wherein the iodide comprises one or more components each independently selected from the group consisting of imidazolium iodide, pyridinium iodide, alkali metal iodide, ammonium iodide, and pyrrolidinium iodide.

15. The dye-sensitized solar cell of claim 11, wherein a pseudohalogen/iodide molar ratio is from about 0.001 to about 10.

16. The dye-sensitized solar cell of claim 11, further comprising dye molecules.
